(19) United States
(12) Patent Application Publication
(10) Pub. No.: US 2004/0179392 A1
(43) Pub. Date: Sep. 16, 2004

(54) Non-volatile memory cell comprising dielectriclayers having a low dielectric constant and corresponding manufacturing process

(76) Inventors: Alessia Pavan, Merate (IT); Cesare Clementi, Busto Arsizio (IT); Livio Baldi, Agrate Brianza (IT)

Correspondence Address: GRAYBEAL, JACKSON, HALEY LLP, 155 - 108TH AVENUE NE, SUITE 350, BELLEVUE, WA, 98004-5901, US

(21) Appl. No.: 10/749,130

(22) Filed: Dec. 30, 2003

(30) Foreign Application Priority Data
Dec. 30, 2002 (EP) 02425805.5

(51) Int. Cl. G11C 11/00

(52) U.S. Cl. 365/154

(57) ABSTRACT

A non-volatile memory cell is described, being integrated on a semiconductor substrate and comprising: A floating gate transistor including a source region and a drain region, a gate region projecting from the substrate and comprised between the source and drain regions, the gate region having a predetermined length and width and comprising a first floating gate region and a control gate region, in which the floating gate region is insulated laterally, along the width direction, by a dielectric layer with low dielectric constant value. A process for manufacturing non-volatile memory cells on a semiconductor substrate is also described, comprising the following steps: form active areas in the semiconductor substrate bounded by an insulating layer, deposit a first conductor material layer on active areas, define through a standard photolithographic technique a plurality of floating gate regions, form a dielectric layer with low dielectric constant value on the floating gate regions.

### PRIORITY CLAIM

This application claims priority from European patent application No. 02425805.5, filed Dec. 30, 2002, which is incorporated herein by reference.

### TECHNICAL FIELD

The present invention relates to a non-volatile memory cell comprising dielectric layers having low dielectric constant and corresponding process.

More specifically, an aspect of the invention relates to a non-volatile memory cell integrated on a semiconductor substrate and comprising:

a floating gate transistor including a source region and a drain region, a gate region projecting from the substrate and comprised between said source and drain regions, said gate region having a predetermined length and width and comprising a first floating gate region and a control gate region.

Another aspect of the invention relates also to a process for manufacturing non-volatile memory cells on a semiconductor substrate, comprising the following steps:

form active areas in said semiconductor substrate bounded by an insulating layer,

form on said active areas a first dielectric material layer,

deposit a first conductor material layer on said first dielectric layer,

define through a standard photolithographic technique a plurality of floating gate regions.

The described embodiments of the invention relate particularly, but not exclusively, to a Flash non-volatile memory cell comprising dielectric layers with low dielectric constant and the following description is made with reference to this field of application for convenience of illustration only.

### BACKGROUND

As it is well known, semiconductor-integrated Flash EPROM memory electronic devices comprise a plurality of matrix-organized non-volatile memory cells 1; i.e. that cells are organized according to rows, referred to as word lines WL, and columns, referred to as bit lines BL, as shown in FIG. 1a.

Each non-volatile cell 1 comprises a floating gate MOS transistor as shown in FIG. 1b. The floating gate region FG of the floating gate transistor is formed above the channel region CH formed in the semiconductor substrate 2 and separated from the latter through a thin oxide layer 3 (tunnel oxide) being about ˜10 nm thick. A control gate region CG is coupled in a capacitive way to the floating gate region FG through a single dielectric layer 7 or comprising several overlapped dielectric layers such as for example ONO (oxide/nitride/oxide).

The other transistor regions are the usual drain, source and body terminals. Metallic electrodes are provided to contact the drain and source terminals and the control gate region CG in order to allow predetermined voltage values to be applied to the memory cell 1.

The charge stored in the floating gate region FG determines the logic state of cell 1 by modifying the threshold voltage thereof: in fact a fundamental feature of the memory cell 1 is to have two states, the one with a low threshold voltage (“erased” cell) and the other with a high threshold voltage (“written” cell). The voltage is applied from the outside to the control gate region CG, but the electrode which effectively controls the channel state is the floating gate region FG.

A known process flow to manufacture Flash memory cells 1 integrated on a semiconductor substrate 2 is shown in FIGS. 2 to 5. These figures are vertical section views in a parallel direction to “Word Lines”.

This known process provides that in the substrate a plurality of active areas, wherein memory cells will be formed, separated from each other by portions of a field oxide layer FOX, are formed. A first dielectric layer 3 referred to as “Tunnel Oxide” and a polycrystalline silicon layer 4 referred to as POLY1 are then formed on the substrate 2.

This polycrystalline silicon layer 4 which is about 50-200 nm thick is formed for example through LPCVD (Low Pressure Chemical Vapor Deposition). This polycrystalline silicon layer 4 is, in case, doped to reduce the resistivity thereof, for example through a phosphorus or arsenic implant or in situ by adding phosphin to the deposition environment.

The process continues with the definition of layer 4 to form a plurality of polycrystalline silicon strips 5 being parallel to each other. These strips 5 are separated and insulated from the substrate 2 by means of the oxide layer 3 as shown in FIG. 3.

Particularly, in this step, a photosensitive material layer 6 referred to as resist is deposited on the substrate 2 surface and it is exposed to a convenient radiation in predetermined areas which are not protected by a mask. The resist portions selectively exposed to the radiation have a higher removing speed than the non-exposed regions and they can thus be removed through a chemical solution referred to as developer. After the lithographic definition a dry etching of the polycrystalline silicon strips 5 is performed to define the floating gate regions FG.

After depositing an interpoly dielectric layer 7, the standard process flow continues with the “Word Line” definition by forming a polycrystalline silicon layer 8 (referred to as Poly2).

“Word Lines” are thus defined through a photolithographic process providing the use of a resist mask so that these word lines are located perpendicularly to the polysilicon strips 5.

Although advantageous under many aspects, this process flow has several drawbacks. In fact the area between two adjacent floating gates is completed with the deposition of the second polysilicon layer 8. Cell 1 is then filled up by dry etching.

Nevertheless, the decrease in size of the area between two adjacent floating gates (˜40-50 nm in the most advanced technologies) makes the filling with a material like polysilicon difficult.

It must be added that the interpoly dielectric layer 7 like ONO, being a high dielectric constant K material, increases the capacitive coupling between adjacent floating gate regions FG. This can cause undesired interactions between adjacent cells, especially if they are in different logic states.

The technical problem underlying embodiments of the present invention is to provide a method for forming non-volatile memory cells, having such structural and functional characteristics as to allow the capacitive coupling between adjacent floating gate regions to be reduced, overcoming thus the limits that currently affect devices manufactured according to the prior art.

### SUMMARY

A solutive idea underlying an aspect of the present invention is to define a process sequence needed to obtain a memory device organized in rows and columns comprising non-volatile memory cells wherein the area between two adjacent floating gate regions belonging to the same row is filled up with low dielectric constant (low-k) material.

On the basis of this solutive idea, according to one aspect of the present invention the technical problem is solved by a memory cell as previously described and defined in the characterising part of claim 1.

According to another aspect of the present invention, the problem is solved also by a process as previously described and defined in the characterising part of claim 7.

The features and advantages of devices according to various aspects of the invention will be apparent from the following description of an embodiment thereof given by way of non-limiting example with reference to the attached drawings.

### BRIEF DESCRIPTION OF THE DRAWINGS

FIG. 1a is a schematic view of a memory cell matrix portion in a semiconductor-integrated memory electronic device;

FIG. 1b is a sectional view along the line I-I of FIG. 1 of a standard memory cell;

FIG. 1c is a sectional view along the line II-II of FIG. 1 of a standard memory cell;

FIGS. 2 to 5 show respective vertical sections in an enlarged scale of a semiconductor substrate portion during a process for manufacturing non-volatile memory cells according to the prior art;

FIGS. 6 and 7 show respective vertical sections in an enlarged scale of a semiconductor substrate portion during a process for manufacturing non-volatile memory cells according a first embodiment of the invention;

FIGS. 8 and 9 show respective vertical sections in an enlarged scale of a semiconductor substrate portion during a process for manufacturing non-volatile memory cells according to a second embodiment of the invention.

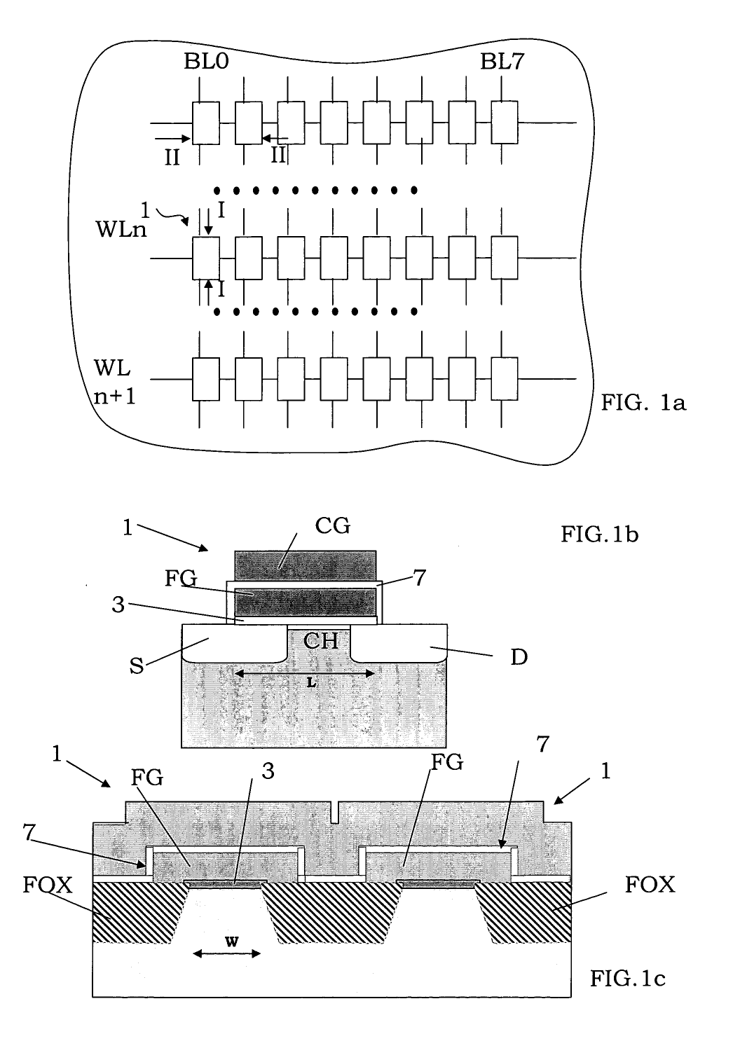

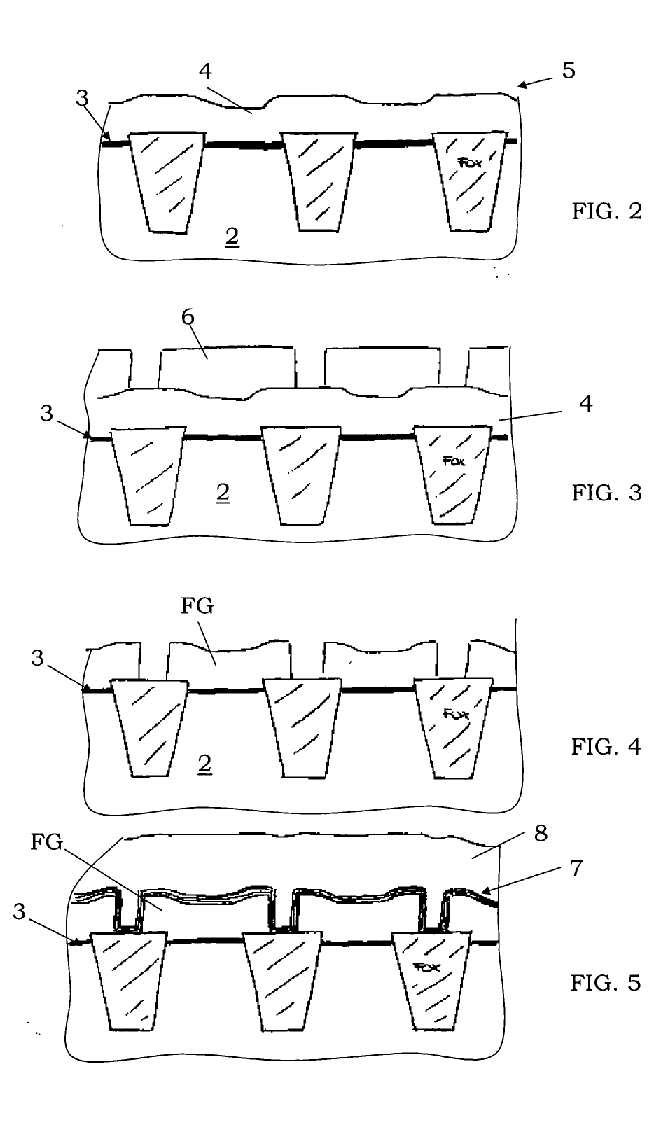

### DETAILED DESCRIPTION

The following discussion is presented to enable a person skilled in the art to make and use the invention. Various modifications to the embodiments will be readily apparent to those skilled in the art, and the generic principles herein may be applied to other embodiments and applications without departing from the spirit and scope of the present invention. Thus, the present invention is not intended to be limited to the embodiments shown, but is to be accorded the widest scope consistent with the principles and features disclosed herein.

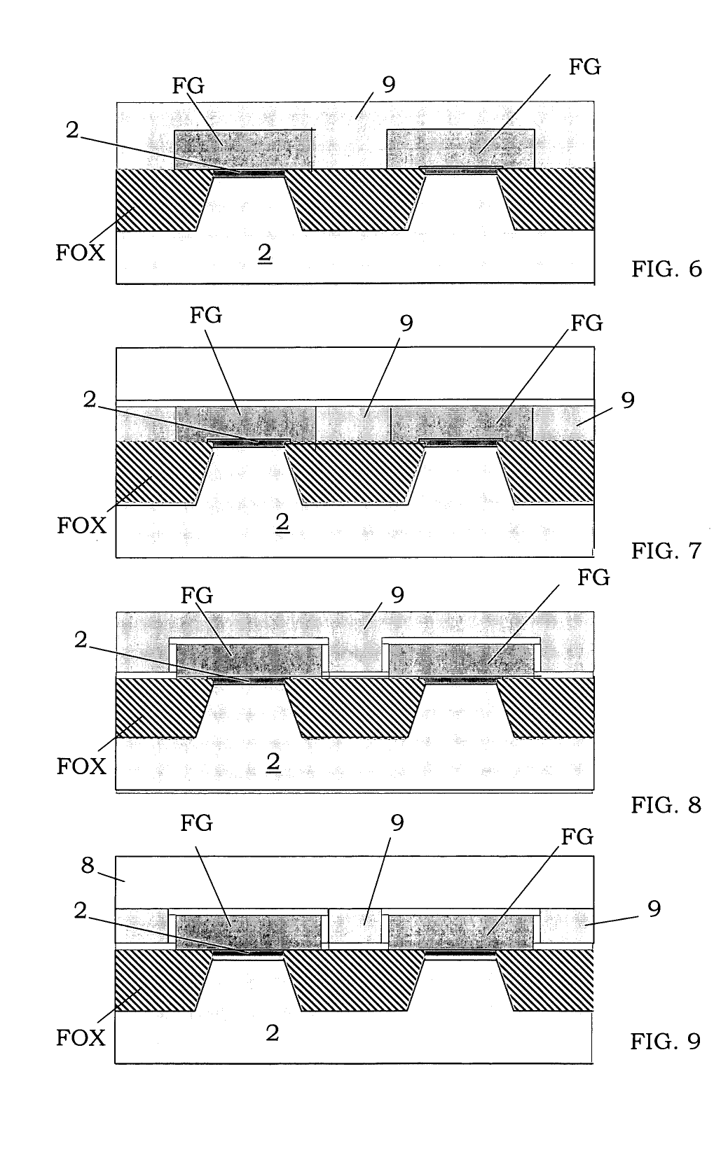

With reference to FIGS. 6 to 9, a floating gate memory cell 1 insulated through dielectric layers with low dielectric constant K value is described.

A corresponding manufacturing process of this cell 1 is also described.

The process steps described hereafter do not form a complete process flow for manufacturing integrated circuits. The described embodiments of the present invention can be implemented together with the techniques for manufacturing integrated circuits currently used in this field, and only those currently used process steps which are necessary for understanding these embodiments of the present invention are included.

The figures which are schematic views of portions of an integrated circuit during the manufacturing thereof are not drawn to scale, but they are instead drawn so as to show the important features of the described embodiments of the present invention.

As described for the prior art, each non-volatile cell 1 comprises a floating gate MOS transistor. The floating gate region FG of the floating gate transistor is formed above the channel region CH formed in the semiconductor substrate 2 and separated by the latter through a thin oxide layer 3 (tunnel oxide), being 6-12 nm thick. A control gate region CG is coupled in a capacitive way to the floating gate region FG through a single dielectric layer 5 or comprising several overlapped dielectric layers such as for example ONO (oxide-nitride-oxide).

According to an embodiment of the invention, a dielectric layer 9 with low dielectric constant is formed between floating gate regions FG belonging to the same memory cell matrix row in order to reduce the coupling between adjacent cells 1.

After all, this dielectric layer 9 with low dielectric constant insulates a floating gate region FG from the adjacent regions along the direction of the memory cell width W.

A process for forming a memory cell 1 according to an embodiment of the invention is now described.

On a substrate 2 a plurality of active areas are formed, wherein memory cells 1, separated from each other by portions of a field oxide layer FOX, will be formed. A first active dielectric layer 3 and a layer 4 made of a conductor material, like for example polycrystalline silicon referred to as POLY1, are then formed on the substrate 2.

Advantageously, this first active dielectric layer 3 is an oxide layer referred to as “Tunnel Oxide” and it is formed on the substrate 2 through a thermal oxidation step.

This polycrystalline silicon layer 4 being about 50-200 nm thick is formed for example through LPCVD (Low Pressure Chemical Vapor Deposition). This polycrystalline silicon layer 4 is, in case, doped to reduce the resistivity thereof, for example through a phosphorus or arsenic implant or in situ by adding phosphin to the deposition environment.

The process continues with the definition of layer 4 to form a plurality of polycrystalline silicon strips 5 being parallel to each other. These strips 5 are separated and insulated from the substrate 2 by means of the oxide layer 3 as shown in FIG. 3.

Particularly, in this step, a photosensitive material layer 6 referred to as resist is deposited on the substrate 2 surface and it is exposed to a convenient radiation in predetermined areas which are not protected by a mask. The resist portions selectively exposed to the radiation have a higher removing speed than the non-exposed regions and they can thus be removed through a chemical solution referred to as developer. After the lithographic definition a dry etching of the polycrystalline silicon strips 5 is performed to define the floating gate regions FG.

Advantageously, a first oxidation step, for example a RTO (Rapid Thermal Oxidation), is performed in a dry environment, obtaining a first very thin dielectric layer of about 1-2 nm, not shown in figures. This first dielectric layer is capable of protecting the walls of the floating gate region FG.

A layer 9 made of a low dielectric constant K material is then formed in order to fill up an area between two adjacent floating gate regions FG belonging to a same small-sized row.

This layer 9 made of a low dielectric constant material is a layer made of an organic or inorganic material such as for example a silicon oxide layer being doped for example with fluorine (FSG Fluorinate Silicate Glass having a dielectric constant comprised between 3.3 and 3.7) or with carbon (for example with alkylic groups, k=2.7-3.1).

These dielectric layers 9 are advantageously deposited through different techniques such as CVD (Chemical Vapor Deposition), HDPCVD (High-Density Plasma Enhanced Chemical Vapor Deposition) or the so-called spin-on-glass technique.

Particularly, the dielectric layers 9 deposited through these latter techniques have also a high planarizing capacity.

Advantageously other dielectric layers 9 are used, such as for example porous silice, with a dielectric constant K which is slightly higher than 1.

Advantageously the dielectric layer 9 is subjected to a densification process in order to improve the constant dielectric thereof.

A selective back etching step towards the polysilicon layer 4 is then performed through CMP or standard back etching techniques in order to leave the floating gate region FG exposed.

The deposition of an interpoly dielectric layer 7 and of a second polysilicon layer 8, being for example about 100-400 nm thick, is performed to form the control gate region of cell 1 as shown in FIG. 7.

A second method for performing the insulation between floating gate regions FG according to another embodiment of the present invention is shown in FIGS. 8-9.

After forming conventionally the floating gate regions FG as shown in FIG. 4, an interpoly dielectric layer 7 is formed.

This interpoly dielectric layer 7 is a single oxide layer (of silicon or hafnium or tellurium or other equivalent materials) or it comprises several overlapped layers such as for example an ONO layer (oxide-nitride-oxide) being about 10-25 nm thick.

A layer 9 made of a low dielectric constant K material is then formed in order to fill up an area between two small-sized adjacent floating gate regions FG.

This layer 9 made of a low dielectric constant material is a layer made of an organic or inorganic material as in the previous embodiment.

A selective back etching towards the interpoly dielectric layer and the deposition of the second polysilicon layer being about 150-250 nm thick (FIG. 9) are then performed, which can be preceded by a slight oxidation (or deposition of an equivalent layer) which, through a short thermal treatment and a secondary impact on the final thickness of the interpoly dielectric layer, succeeds in insulating the low-k material from the above polysilicon layer, inhibiting the mutual interaction.

This second method is obviously applied when the distance between two adjacent floating gates is higher than twice the effective thickness of the high-k dielectric layer 7 (ONO or other above-mentioned multi-layer materials) deposited on the walls of the floating gate region FG.

In conclusion, the insertion of a layer with low dielectric constant value reduces interaction problems between adjacent floating gate regions FG caused by the reduction of the area between two adjacent regions FG.

This process is thus particularly advantageous when using dielectric material layers with high dielectric constant value K as interpoly dielectric layers to improve the capacitive couplings in memory cells 1.

Flash memory cells formed according to the described embodiments of the present invention may be contained in a FLASH memory device or other integrated circuit including such a FLASH memory device. Moreover, such a FLASH memory device or other integrated circuit may be contained in a variety of different types of electronic systems, such as a computer system.

From the foregoing it will be appreciated that, although specific embodiments of the invention have been described herein for purposes of illustration, various modifications may be made without deviating from the spirit and scope of the invention.

1. A non-volatile memory cell integrated on a semiconductor substrate and comprising:
a floating gate transistor including a source region and a drain region, a gate region projecting from the substrate and comprised between said source and drain regions, said gate region having a predetermined length and width and comprising a first floating gate region and a control gate region,
characterised in that said floating gate region is insulated laterally, along the width direction, by a dielectric layer with low dielectric constant value.

2. A memory cell according to claim 1, characterised in that said floating gate regions are covered by a dielectric layer before being insulated from each other through said dielectric layer with low dielectric constant value.

3. A memory cell according to claim 1, characterised in that said dielectric layer with low dielectric constant value is bounded between said floating gate regions.

4. A memory cell according to claim 1, characterised in that said dielectric layer with low dielectric constant value is formed by a layer of material having a dielectric constant comprised between 1 and 3.9.

5. A memory cell according to claim 1, characterised in that said dielectric layer with low dielectric constant value is formed by a silicon oxide layer doped for example with fluorine.

6. A memory cell according to claim 1, characterised in that said dielectric layer with low dielectric constant value is formed by a carbon oxide layer hydrated with alkylic groups.

7. A process for manufacturing non-volatile memory cells on a semiconductor substrate organized in rows and columns to form a memory cell matrix, comprising the following steps:
form active areas in said semiconductor substrate bounded by an insulating layer,
form on said active areas a first dielectric material layer,
deposit a first conductor material layer on said first dielectric material layer,
define through a standard photolithographic technique a plurality of floating gate regions in said first conductor material layer, characterised in that it comprises the following steps:
form a dielectric layer with low dielectric constant value on said floating gate regions.

8. A process for manufacturing non-volatile memory cells according to claim 7, characterised in that said dielectric layer with low dielectric constant value is bounded between said adjacent floating gate regions belonging to the same row.

9. A process for manufacturing non-volatile memory cells according to claim 7, characterised in that said dielectric layer with low dielectric constant value is deposited through CVD techniques.

10. A process for manufacturing non-volatile memory cells according to claim 7, characterised in that said dielectric layer with low dielectric constant value is deposited through spin on glass techniques.

11. A process for manufacturing non-volatile memory cells according to claim 7, characterised in that said dielectric layer with low dielectric constant value is formed by a layer of material having a dielectric constant comprised between 1 and 3.9.

12. A process for manufacturing non-volatile memory cells according to claim 7, characterised in that said dielectric layer with low dielectric constant value is formed by a silicon oxide layer doped for example with fluorine.

13. A process for manufacturing non-volatile memory cells according to claim 7, characterised in that said dielectric layer with low dielectric constant value is formed by a carbon oxide layer hydrated with alkylic groups.

14. A process for manufacturing non-volatile memory cells according to claim 7, characterised in that said floating gate regions are covered by a dielectric layer before being insulated from each other through said dielectric layer with low dielectric constant value.

15. A memory cell matrix formed on a semiconductor substrate comprising a plurality of memory cells organized in rows and columns, each cell being formed according to claim 1, the cell matrix being characterised in that adjacent memory cells belonging to a same row of said memory cell matrix are insulated from each other by a dielectric layer with low dielectric constant value.

16. A memory-cell structure formed on a semiconductor substrate, the memory-cell structure comprising a plurality of non-volatile memory cells arranged in rows and columns and formed on the semiconductor substrate, each memory cell including a floating gate region and the memory-cell structure including an insulating region having a relatively low dielectric constant formed between adjacent floating gate regions of memory cells in respective rows of the structure.

17. The memory-cell structure of claim 16 further comprising a dielectric layer having a greater dielectric constant than the insulating regions formed on the floating gate regions.

18. The memory-cell structure of claim 16 wherein the insulating layer has a dielectric constant having a value of between approximately 1 and approximately 3.9.

19. The memory-cell structure of claim 16 each memory cell further comprises a control gate region capacitively coupled to the floating gate region through a dielectric layer having a dielectric constant greater than that of the insulating layer, and wherein the control gate regions of memory cells in respective rows are electrically interconnected.

20. The memory-cell structure of claim 16 wherein each memory cell comprises a FLASH memory cell.

21. A memory device, comprising:
a memory-cell array formed on a semiconductor substrate, the memory-cell array comprising a plurality of non-volatile memory cells arranged in rows and columns and formed on the semiconductor substrate, each memory cell including a floating gate region and the memory-cell array including an insulating region having a relatively low dielectric constant formed between adjacent floating gate regions of memory cells in respective rows of the array.

22. The memory device of claim 21 wherein the memory device comprises a FLASH memory device and each memory cell comprises a FLASH memory cell.

23. The memory device of claim 21 further comprising a dielectric layer having a greater dielectric constant than the insulating regions formed on the floating gate regions.

24. An electronic system, comprising:
a memory device including,
a memory-cell array formed on a semiconductor substrate, the memory-cell array comprising a plurality of non-volatile memory cells arranged in rows and columns and formed on the semiconductor substrate, each memory cell including a floating gate region and the memory-cell array including an insulating region having a relatively low dielectric constant formed between adjacent floating gate regions of memory cells in respective rows of the array.

25. The electronic system of claim 24 wherein the electronic system comprises a computer system.

26. The electronic system of claim 25 wherein the memory device comprises a FLASH memory device and each memory cell comprises a FLASH memory cell.

27. A method of forming an array of memory cells on a semiconductor substrate, the method comprising:
forming a plurality of memory cells on the substrate and arranged in rows and columns, each memory cell including a respective floating gate region; and
forming a first dielectric region between the floating gate regions of adjacent memory cells in respective rows of memory cells, the first dielectric layer having a relatively small dielectric constant.

28. The method of claim 27 further comprising:
forming a second dielectric layer on the floating gate regions, the second dielectric layer having a dielectric constant that is greater than the dielectric constant of the first dielectric layer; and
forming a control gate region for each memory cell on the second dielectric layer adjacent the corresponding floating gate region.

29. The method of claim 27 wherein each first dielectric region has dielectric constant of between approximately 1 and approximately 3.9.

30. The method of claim 29 wherein the each first dielectric region comprises a silicon oxide layer doped with fluorine.
